(19) United States
(12) Patent Application Publication
(10) Pub. No.: US 2006/0133146 A1
(43) Pub. Date: Jun. 22, 2006

(54) Semiconductor device and a method of manufacturing the same

(76) Inventors: Keiichi Maekawa, Hitachinaka (JP); Shinichi Minami, Koadaire (JP); Kozo Watanabe, Tokyo (JP); Shiro Kamohara, Hachioji (JP); Shoji Yoshida, Akishima (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/297,392

(22) Filed: Dec. 9, 2005

(30) Foreign Application Priority Data
Dec. 10, 2004 (JP) 2004-358083

(51) Int. Cl. G11C 16/04

(52) U.S. Cl. 365/185.14

(57) ABSTRACT

A semiconductor device having a well region of a first conduction type formed in a main surface of a semiconductor substrate, and a nonvolatile memory element formed at the well region is provided. The nonvolatile memory element comprises a gate electrode formed over the well region through an insulating film for charge storage, and a source region and drain region of a second conduction type which are separated from each other and are disposed in the well region. The well region includes a third semiconductor region, a second semiconductor region which is arranged at a position deeper than the third semiconductor region, and a first semiconductor region that is arranged at a position deeper than the second semiconductor region. The first and third semiconductor regions, respectively, have an impurity concentration higher than the second semiconductor region.

### CROSS-REFERENCE TO RELATED APPLICATION

The present application claims priority from Japanese patent application No. 2004-358083 filed on Dec. 10, 2004, the content of which is hereby incorporated by reference into this application.

### BACKGROUND OF THE INVENTION

This invention relates to a semiconductor device and a manufacturing technique therefor. More particularly, the invention relates to a technique effective for application to a semiconductor device having a nonvolatile memory element.

For a semiconductor device, a nonvolatile semiconductor memory device called, for example, a flush memory is known. In the memory cells of this flush memory, there are known a one-transistor system constituted of one nonvolatile element, and a two-transistor type wherein one nonvolatile memory element and one MISFET (metal insulator semiconductor field effect transistor) for selection are connected in series. The nonvolatile memory elements known in the art are those of a floating gate type wherein information is memorized in a floating gate electrode between a semiconductor substrate and a control gate electrode, a MNOS (metal nitride oxide semiconductor) type wherein an ON (oxide/nitride) film is used as a gate insulating film between a semiconductor substrate and a gate electrode and information is memorized in the gate insulating film, and a MONOS (metal oxide nitride oxide semiconductor) type wherein an ONO (oxide/nitride/oxide) film is used as a gate insulating film (insulating film for information storage) between a semiconductor substrate and a gate electrode and information is memorized in this gate insulating film.

For instance, Japanese Unexamined Patent Application No. 2000-216271 discloses a floating gate nonvolatile memory element wherein a threshold voltage is controlled by injection, into a control gate electrode, of charges generated through avalanche breakdown.

The invention particularly relates to a disturb mode of a MONOS nonvolatile memory element.

### SUMMARY OF THE INVENTION

We made studies on a semiconductor device having a MONOS nonvolatile memory element and, as a result, found the following problems involved therein.

In a nonvolatile MONOS memory mounted in IC cards, when a negative high voltage stress is continuedly exerted on a gate electrode and a substrate (well region) through bits (memory cells) wherein electrons have been injected into a charge retention layer (i.e. an insulating film (ONO film) for charge storage), a disturb mode wherein a threshold voltage lowers takes place, with a possibility that troubles arise in product operation. This disturb mode involved in the stress occurs such that the potential difference between a diffusion layer and a substrate (or a gate electrode) is so great that hot holes are produced at the pn junction of the diffusion layer and the substrate, and these holes are injected into the charge retention layer, thereby causing the disturb to occur. This phenomenon is suggested from the following two points.

(1) The junction leak between the diffusion layer and the substrate has strong dependence on gate bias. It is thus considered that the hot holes occur in the vicinity of a shallow diffusion layer beneath the end portion of the gate electrode, at which an electric field is liable to concentrate, and are attracted toward the charge retention layer by the influence of negative gate bias.

(2) It is considered that the mode is accelerated at a short-channel side, so that the hot holes are attracted toward the charge retention layer by this short-channel effect accompanied by lowering of surface potential.

In view of the above, we contemplate to provide a structure wherein the position of occurrence of hot holes is kept apart from the gate electrode so that the hot holes becomes unlikely to suffer the influence of the gate bias and surface potential, and thus the injection efficiency of the charge retention layer is reduced, thereby suppressing the occurrence of the disturb. The invention has been accomplished based on this.

It is accordingly an object of the invention to provide a technique related to a semiconductor device having a nonvolatile memory element, in which the efficiency of injection of hot holes occurring by application of stress into a charge storage layer can be reduced.

It is another object of the invention to provide a technique capable of improving reliability of a semiconductor device having a nonvolatile memory element.

The above and other object and novel features of the invention will become apparent from the following description with reference to the drawings attached herewith.

Typical embodiments of the invention are summarized below.

The disturb mode is considered to mainly occur as follows: hot holes that generate at a high electric field site below a gate electrode end portion upon stress being exerted are injected into a charge retention layer. Hence, a well region at a depth in the vicinity of a junction depth (Xj) of a deep diffusion layer is highly concentrated to make a fresh high electric field region beneath or below the deep diffusion layer as kept apart from the gate electrode, with the result that the position of occurrence of the hot holes can be kept apart from the charge retention layer. More particularly, the semiconductor devices are so arranged as set out hereinbelow, for example.

(1) A semiconductor device having a well region of a first conduction type formed in a main surface of a semiconductor substrate, and a nonvolatile memory element formed at the well region of the first conduction type, wherein the nonvolatile memory element comprises:

a gate electrode formed over the well region of the first conduction type through an insulating film for charge storage; and

a source region and drain region of a second conduction type which are separated from each other along a gate length of the gate electrode and are disposed in the well region of the first conduction type, and

wherein the well region of the first conduction type comprises:

a third semiconductor region arranged between the source region and the drain region and in contact with the source region, the drain region and the insulating film for charge storage;

a second semiconductor region which is disposed between the source region and the drain region and which is arranged at a position deeper than the third semiconductor region as viewed toward a direction of depth from the main surface of the semiconductor substrate and is in contact with the source region, the drain region and the third semiconductor region; and

a first semiconductor region that is located at a position deeper than the second semiconductor region as viewed toward a direction of depth from the main surface of the semiconductor substrate and is in contact with the source region, the drain region and the second semiconductor region, the first and third semiconductor regions being higher in impurity concentration than the second semiconductor region.

In (1) above, the depth of junction between the source region and the drain region is greater than the third semiconductor region.

In (1) above, the first semiconductor region is lower in impurity concentration than the third semiconductor region.

In (1) above, when a potential is applied to the gate electrode and the well region of the first conduction type, a high electric field is established at a junction between the source region and the first semiconductor region.

In (1) above, when a potential is applied to the gate electrode and the well region of the first conduction type, a first high electric field region is established at a surface portion below the end portion of the gate electrode in the source region and a second high electric filed is established at a junction between the source region and the first semiconductor region.

(2) A semiconductor device comprising a well region of a first conduction type formed in a main surface of a semiconductor substrate and a nonvolatile memory element formed in the well region of the first conduction type,

wherein the nonvolatile memory element includes a gate electrode formed over the well region of the first conduction type through an insulating film for charge storage, and a source region and drain region, both being of a second conduction type, which are positioned in the well region of the first conduction type as kept apart from each other along a gate length of the gate electrode, and

wherein the well region of the first conduction type has first and second impurity concentration peaks in an impurity concentration distribution from the main surface toward a direction of depth of the semiconductor substrate so that the first impurity peak is located at a region shallower than the source region and the drain region, and the second impurity concentration peak is located at a region deeper than the source region and the drain region.

In (2) above, the second impurity concentration peak is located in the vicinity of a junction depth of the source region and the drain region.

In (2) above, when a potential is applied to the electrode and the well region of the first conduction type, a high electric field region is established at a junction between the source region and the well region.

In (2) above, when a potential is applied to the gate electrode and the well region of the first conduction type, a first high electric filed region is established at a surface portion below the end portion of the gate electrode in the source region and a second high electric filed region is established at a junction between the source region and the well region.

The effects of the typical embodiments according to the invention are briefly described below.

According to the invention, the semiconductor device having a nonvolatile memory element can be reduced with respect to an efficiency of injection, into a charge storage layer, of hot holes occurring on application of stress.

According to the invention, reliability of the semiconductor device having a nonvolatile memory element can be improved.

### BRIEF DESCRIPTION OF THE DRAWINGS

FIG. 1 is an equivalent circuit diagram showing an arrangement of a memory cell array of a flush memory (semiconductor device) according to Embodiment 1 of the invention;

FIG. 2 is a schematic sectional view showing a general arrangement of a nonvolatile memory element mounted in the memory array;

FIG. 3 is a schematic, enlarged, sectional view of part of FIG. 2;

FIGS. 4(a) and 4(b) are, respectively, an impurity concentration distribution wherein FIG. 4(a) is an impurity concentration distribution taken along line a-a of FIG. 3 and FIG. 4(b) is an impurity concentration distribution taken along line b-b of FIG. 3;

FIGS. 5 to 15 are, respectively, a schematic sectional view showing a manufacturing step of a flush memory according to Embodiment 1 of the invention;

FIG. 16 is a view showing a state of voltage application upon erasing of data in a memory array;

FIG. 17 is a view showing a state of voltage application upon writing of data in the memory cell array;

FIG. 18 is a view showing a state of voltage application upon reading of data from the memory cell array;

FIG. 19 is a view showing a disturb model in a nonvolatile memory element;

FIG. 20(a) is a view showing the results of calculation through two-dimensional simulation of an electric field and junction leak upon application of a stress capable of causing a disturb to occur under conditions where electrons are retained in a charge retention layer of a nonvolatile memory element having a novel structure according to the invention and FIG. 20(b) is a similar view but for a nonvolatile memory element having a conventional structure;

FIG. 21 is a graph showing a threshold voltage (found value) in relation to time when a stress capable of causing a disturb to occur is continuedly exerted under conditions where electrons are retained in a charge retention layer of a nonvolatile memory element;

FIG. 22 is a schematic sectional view showing a general arrangement of a nonvolatile memory element mounted in a flush memory according to Embodiment 2 of the invention; and

FIGS. 23 to 26 are, respectively, a manufacturing step of the flush memory according to Embodiment 2 of the invention.

### BEST MODE FOR CARRYING OUT THE INVENTION

Embodiments of the present invention will be described in detail hereinunder with reference to the accompanying drawings. In all of the drawings for illustrating the following embodiments, portions having the same functions are identified by like reference numerals, and repeated explanations thereof will be omitted.

### Embodiment 1

In Embodiment 1, an instance of application of the invention to a flush memory (semiconductor device) wherein a memory cell is constituted of a MONOS nonvolatile memory element.

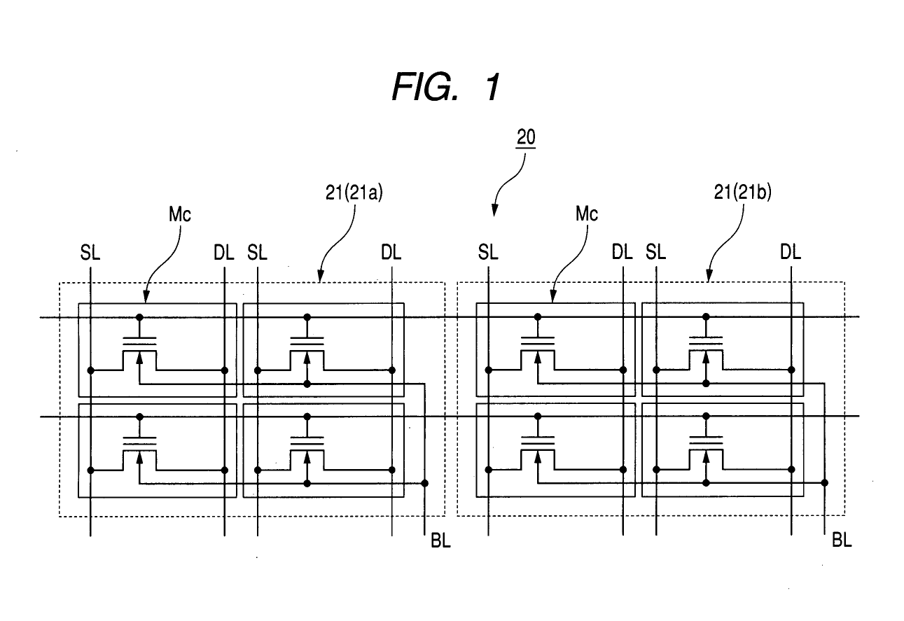

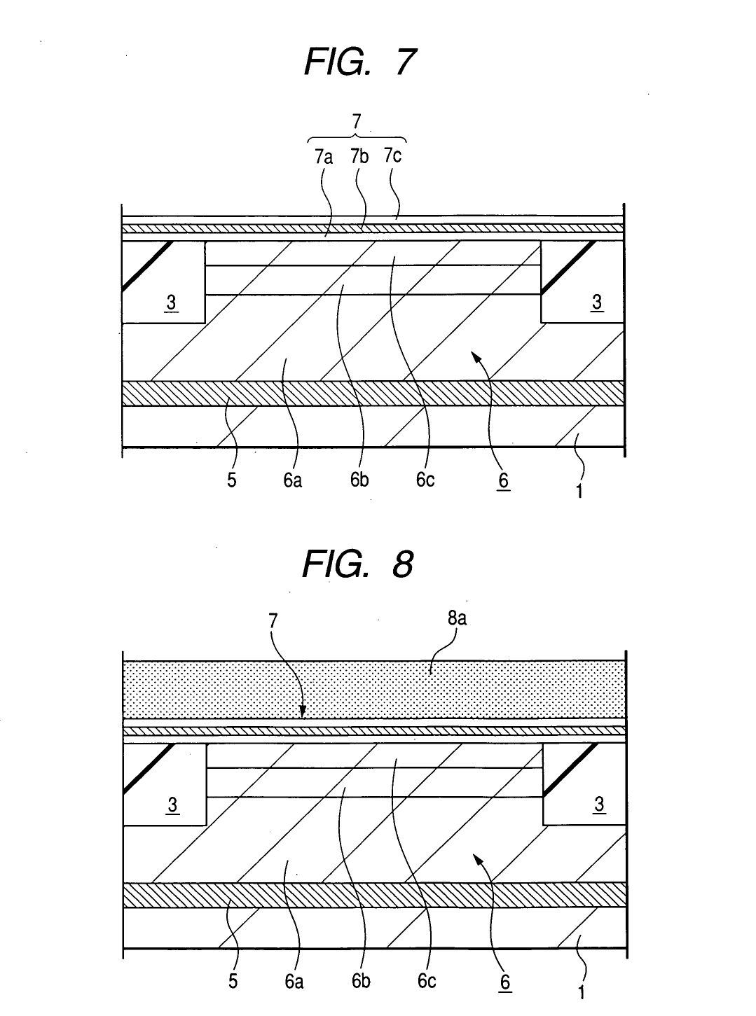

FIGS. 1 to 15 are views related to a flush memory according to Embodiment 1 of the invention, respectively.

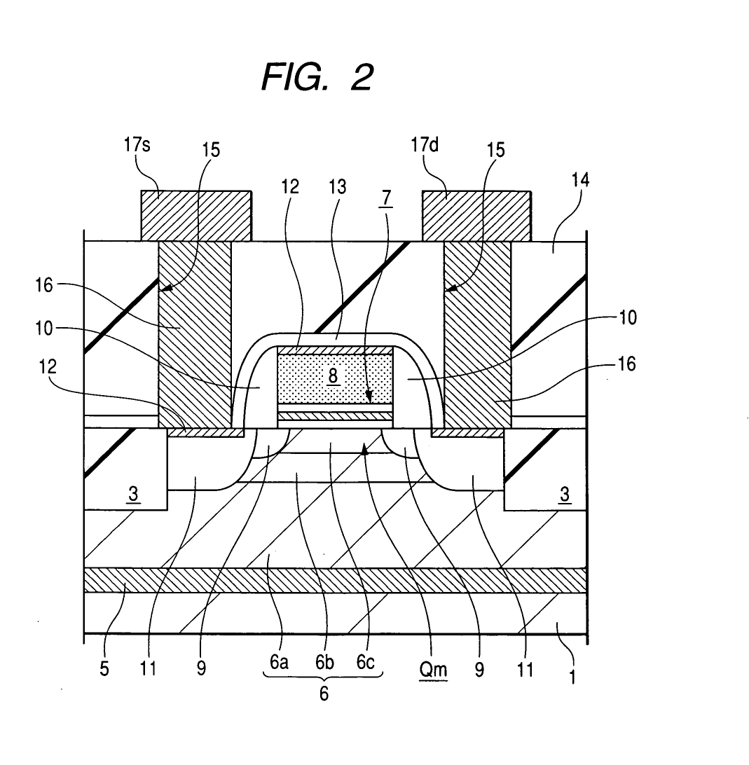

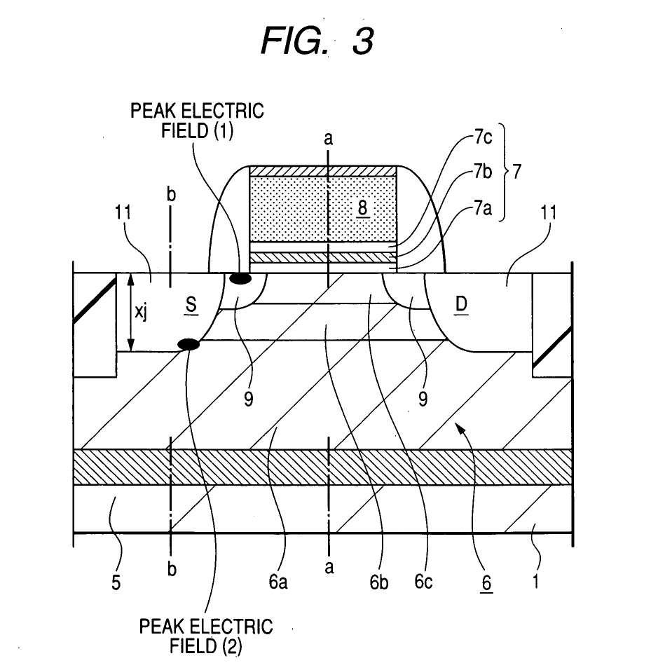

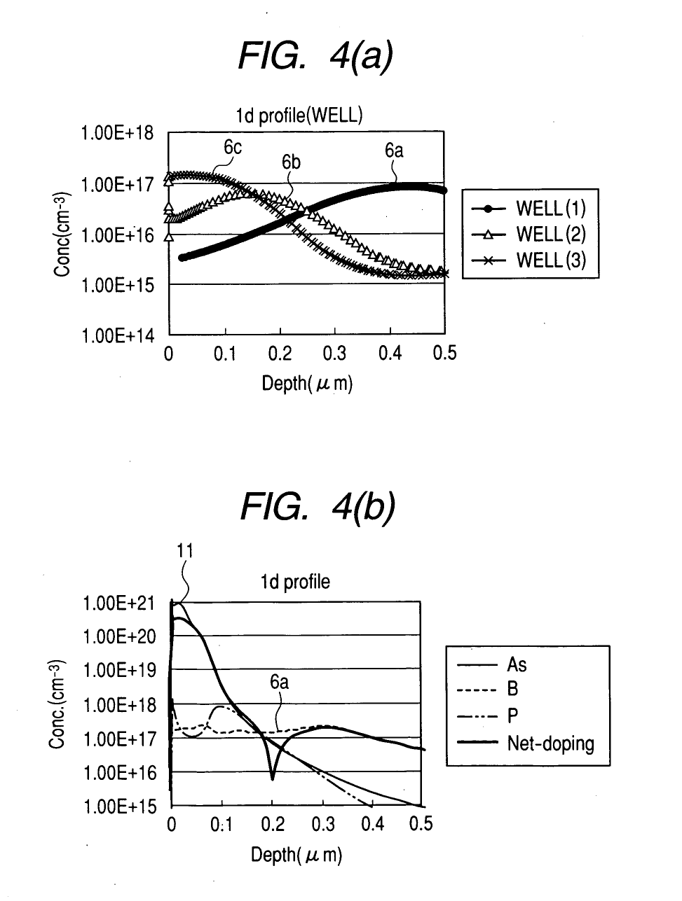

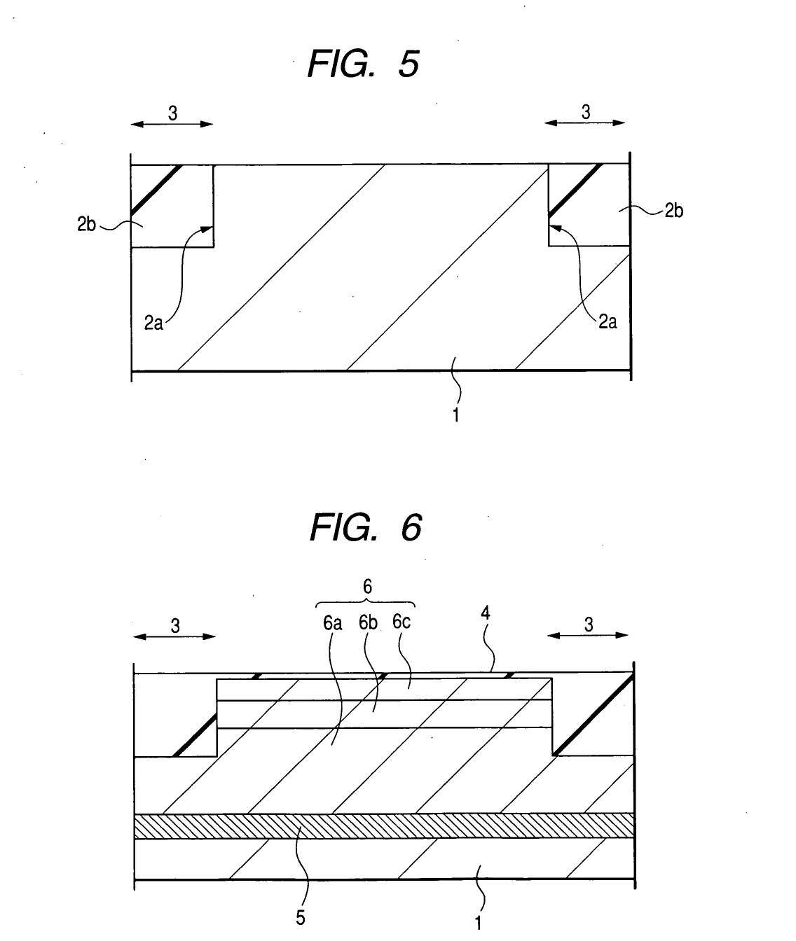

More particularly, FIG. 1 is an equivalent circuit diagram showing a memory array arrangement of the flush memory (semiconductor device), FIG. 2 is a schematic sectional view showing a schematic arrangement of nonvolatile memory elements mounted in the memory cell array, and FIG. 3 is a schematic, enlarged, sectional view of part of FIG. 2. FIGS. 4(a) and 4(b) are, respectively, an impurity concentration distribution wherein FIG. 4(a) is a graph showing an impurity concentration distribution along line a-a of FIG. 3 and FIG. 4(b) is an impurity concentration distribution along line b-b of FIG. 3. FIGS. 5 to 15 are, respectively, a schematic sectional view showing a manufacturing step of the flush memory.

As shown in FIG. 1, a memory cell array 20 of a flush memory has a plurality of memory cells Mc arranged plurally in a matrix. One memory cell Mc is constituted of one nonvolatile memory element Qm shown in FIG. 2. In the memory array 20, a plurality of word lines WL extending along a direction of X are arranged, and a plurality of source liens SL extending along a direction of Y are also arranged with a plurality of data lines DL being arranged as shown.

The plural memory cells Mc are divided into a plurality of memory cell blocks 21 (including, for example, 21a, 21b . . . ) each having a plurality of memory cells Mc. The memory cells Mc in the respective blocks 21 are formed on the same well region, and a well line BL is arranged in the well region of each block 21.

As shown in FIG. 2, the flush memory is mainly constituted, as a semiconductor substrate, of a silicon substrate 1 made, for example, of p-type single crystal silicon.

The main surface (element forming region, circuit forming region) of the silicon substrate 1 has element forming regions partitioned with an element isolation region (non-active region) 3. The element forming region is formed with an n-type well region 5 for isolation, a p-type well region 6 and a nonvolatile memory element Qm. Although not depicted in detail, the p-type well region 6 is formed in the n-type well region for isolation while being isolated in every memory cell block 21 of the memory cell array. Individual p-type well regions 6 are electrically isolated from each other by means of the n-type well region 5 for isolation.

The element isolation region 3 is formed, for example, of a shallow trench isolation (STI) region although not limited thereto. The shallow trench isolation region is formed by forming a shallow trench in the main surface of the silicon substrate 1 and selectively burying an insulating film (e.g. a silicon oxide film) inside the shallow trench.

The nonvolatile memory element Qm has an insulating film 7 for charge storage mainly functioning as a channel forming region and a charge storage portion, a gate electrode 8, and a source region and drain region.

In the element forming region in the main surface of the silicon substrate 1, the insulating film 7 for charge storage is formed on the p-type well region 6, the gate electrode 8 is formed on the p-type well region 6 through the insulating film 7 for charge storage, and the channel forming region is formed in the surface layer portion of the silicon substrate 1 beneath the gate electrode 8. The source region and drain region are kept apart from each other along the gate length of the gate electrode 8. In other words, the p-type well region 6 is formed as sandwiching the channel forming region therebetween along the channel length of the channel forming region.

The source region and drain region of the nonvolatile memory element Qm has a pair of n-type semiconductor regions (impurity diffusion layers) 9 serving as an extension region and a pair of n-type semiconductor regions (impurity diffusion regions) 11 serving as a contact region. The n-type semiconductor region 9 is formed in the p-type well region 6 in alignment with the gate electrode 8. The n-type semiconductor region 11 is formed in the p-type well region 6 in alignment with a side wall spacer 10 that is provided at the side wall of the gate electrode 8.

The n-type semiconductor region 11 acting as the contact region has an impurity concentration higher than the n-type semiconductor region 9 serving as the extension region. More particularly, the nonvolatile memory element Qm of Embodiment 1 has an LDD (lightly doped drain) structure where an impurity at a channel forming region side of the drain region is rendered low in concentration. The LDD structure is able to reduce a degree of diffusion of the drain region toward the channel forming region side and ensures a dimension of channel length, thereby suppressing occurrence of a short channel effect. In addition, the gradient of an impurity concentration distribution at the pn junction formed between the drain region and the channel forming region is mitigated to lower the intensity of electric field produced in this region, and thus, an amount of hot carriers can be reduced.

The gate electrode 8 is formed of a polysilicon film into which an impurity capable of reducing a resistance is introduced, for example. The gate electrode 8 is formed of part of the word line WL, that is, it is formed integrally with the word line WL.

The n-type semiconductor region 11 and the gate electrode 8 are, respectively, formed on the surface thereof, for example, with a cobalt silicide (CoSi) layer 12 as a silicide layer (metal/semiconductor reaction layer) for rendering them low in resistance. These cobalt silicide layers 12 are formed in alignment with the side wall spacer 10, for example, according to a salicide ( self aligned silicide) technique. In this sense, the nonvolatile memory element Qm of this Embodiment 1 becomes a salicide structure.

The silicon substrate 1 is formed, on the main surface thereof, with an interlayer insulating film 14 made, for example, of a silicon oxide film. An insulating film 13 made, for example, of a silicon nitride film is provided between the main surface of the silicon substrate 1 and the interlayer insulating film 14. This insulating film 13 functions as an etching stopper film when the interlayer insulating film 14 is etched to form a connection hole.

A connection hole 15 which reaches from the surface of the interlayer insulating film 14 to the cobalt silicide layer 12 is provided over one n-type semiconductor region 11 (left side as viewed in FIG. 1) of the paired n-type semiconductor regions 11. A conductive plug 16 is buried in the connection hole 15. The one n-type semiconductor region 11 is electrically connected to a wiring 17s extending over the interlayer insulating film 14 via the cobalt silicide layer 12 and the conductive plug 16. The wiring 17s is, in turn, electrically connected to a source line SL shown in FIG. 1.

The other n-type semiconductor region 11 (right side as viewed in FIG. 1) of the paired n-type semiconductor regions 11 is provided thereover with a connection hole 15 that reaches from the surface of the interlayer insulating film 14 to the cobalt silicide layer 12. The connection hole 15 is buried with a conductive plug 16 therein. The other n-type semiconductor region 11 is electrically connected to a wiring 17d extending over the interlayer insulating film 14 via the cobalt silicide layer 12 and the conductive plug 16. The wiring 17d is electrically connected to a data line DL shown in FIG. 1.

The insulating film 7 for charge storage is formed of an ONO (oxide/nitride/oxide) film. In Embodiment 1, this film 7 is formed of an ONO film made, for example, of a silicon oxide (SiO) film 7a/silicon nitride (SiN) film 7b/silicon oxide (SiO) film 7c arranged in this order as viewed from the main surface side of the silicon substrate 1. The silicon nitride film 7b of the insulating film 7 for charge storage acts as a charge protection layer.

The nonvolatile memory element Qm changes a threshold voltage (Vth) when hot electrons are injected into the trap inside the silicon nitride film (charge retention layer) 7b of the insulating film 7 for charge storage beneath the gate electrode 8. More particularly, the nonvolatile memory element Qm has such a structure that when charges are stored in the insulating film 7 for charge storage, the threshold voltage of drain current passing between the source and drain is controlled thereby performing memory operation.

It will be noted that the film injecting hot electrons in the insulating film 7 for charge storage is not limited to a silicon nitride film, but there may be used, for example, an insulating film containing nitrogen in the film such as a silicon oxide nitride (SiON) film. When using such a silicon oxide nitride film, the breakdown voltage of the insulating film 7 for charge storage can be more enhanced in comparison with a silicon nitride film. Thus, a deterioration resistance of carrier mobility in the substrate surface (i.e. in the vicinity of the interface between the substrate and the insulating film for charge storage) beneath the gate electrode 8, which depends on the injection cycle of hot electrons, can be enhanced.

As shown in FIG. 3, writing operation of the nonvolatile memory element Qm is carried out in such a way that a voltage of −10.7 V is applied to the drain region D, 1.5 V applied to the source region S, 1.5 V applied to the gate electrode 8 and −10.7 V applied to the p-type well region 6, respectively, thereby causing hot electrons to be injected from the channel forming region side (substrate side) below the gate electrode 8 into the silicon nitride film 7b of the insulating film 7 for charge storage. The hot electrons are injected by passage through the silicon oxide film 7a that is a lower layer of the insulating film 7 for charge storage.

The erasing operation of the nonvolatile memory element Qm is carried out in such a way that under a floating condition of the drain region D, a voltage of 1.5 V is applied to the source region S and p-type well region 6, respectively, and −8.5 V applied to the gate electrode 8, thereby causing hot holes to be injected from the channel forming region side (substrate side) below the gate electrode 8 via the silicon oxide film 7a, used as a lower layer of the insulating film 7 for charge storage, into the silicon nitride 7b of the insulating film 7 for charge storage.

The reading operation of the nonvolatile memory element Qm is performed by application of 0.8 V to the drain region D, 0 V to the source region S, 0 V to the gate electrode 8 and 0 V to the p-type well region 6, respectively.

As shown in FIG. 3, the p-type well region 6 is constituted of p-type semiconductor regions 6c, 6b and 6a arranged in this order as viewed from the main surface of the silicon substrate 1 toward a direction of depth.

The p-type semiconductor region 6c is arranged between the source region and drain region, and is in contact with the source region, drain region and the silicon oxide film 7a of the insulating film 7 for charge storage.

The p-type semiconductor region 6b is arranged between the source region and drain region at a position deeper than the p-type semiconductor region 6c as viewed from the main surface of the silicon substrate 1 toward a direction of depth, and is in contact with the source region, drain region and p-type semiconductor region 7c.

The p-type semiconductor region 6a is arranged at a position deeper than the p-type semiconductor region 6b as viewed from the main surface of the silicon substrate 1 toward a direction of depth and is in contact with the source region, drain region and p-type semiconductor region 6c.

The p-type semiconductor regions 6c and 6a are, respectively, formed at an impurity concentration higher than the p-type semiconductor region 6b. The p-type semiconductor region 6a is formed at an impurity concentration lower than the p-type semiconductor substrate 6c. The junction depth Xj (i.e. a depth from the main surface of the substrate) of a pair of p-type semiconductor regions 11 serving as the source region and drain region is larger than that of the p-type semiconductor region 6c, and particularly in Embodiment 1, is determined to be larger than the p-type semiconductor region 6b.

FIGS. 4(a) and 4(b) are, respectively, a view showing an impurity concentration distribution wherein FIG. 4(a) is a graph showing an impurity concentration distribution taken along line a-a of FIG. 3 and FIG. 4(b) is a similar graph but with the distribution taken along line b-b of FIG. 3.

As stated hereinbefore, the p-type well region 6 is so formed that the p-type semiconductor regions 6c and 6a are higher in impurity concentration than the p-type semiconductor region 6b. Thus, the region 6 is so configured as to have a first impurity concentration peak corresponding to an impurity distribution of the p-type semiconductor region 6c and a second impurity concentration peak corresponding to an impurity distribution of the p-type semiconductor region 6a as is particularly shown in FIGS. 4(a) and 4 (b). The first impurity concentration peak (p-type semiconductor region 6c) is located at a position shallower than the junction depth Xj of the n-type semiconductor region 11. The second impurity concentration peak (p-type semiconductor region 6a) is located at a position deeper than the junction depth Xj of the n-type semiconductor region 11 and is in the vicinity of the junction depth Xj of the n-type semiconductor region 11.

As will be described in more detail, application of voltages to the gate electrode 8 and the p-type well region 6 permits the nonvolatile memory element Qm arranged in this way to establish a first high electric field region at a surface portion below the end of the gate electrode 8 of the source region and a second high electric field region established at a junction between the source region (n-type semiconductor region 11) and the p-type semiconductor region 6a.

Next, the manufacture of a memory flush is illustrated with reference to FIGS. 5 to 15.

Initially, a silicon substrate 1 made of p-type single crystal silicon having a specific resistance, for example, of about 10 Ωcm is provided as a semiconductor substrate. Thereafter, as shown in FIG. 5, an element isolation region 3 defining an element forming region is formed in the main surface of the silicon substrate 1. The element isolation region 3 is formed by use, for example, of a known STI technique although not limitative. More particularly, the element isolation region 3 is formed with a shallow trench (e.g. a trench having a depth, for example, of about 300 nm) in the main surface of the silicon substrate 1. Thereafter, an insulating film 2b made of a silicon oxide film is deposited over the main surface of the silicon substrate 1 including the inside of the shallow trench 2a according to a CVD (chemical vapor deposition) method. The insulating film 2b is removed from the main surface of the silicon substrate 1 according to a CMP (chemical mechanical polishing) method while selectively leaving the insulating film 2b inside the shallow trench 2a, thereby forming the element isolation region 3.

Next, thermal oxidation treatment is carried out to form a buffer insulating film 4 made of a silicon oxide film at the element forming region of the main surface of the silicon substrate 1.

The ion implantation of an impurity is carried out in the main surface of the silicon substrate 1, and thermal treatment is carried out to activate the impurity. As shown in FIG. 6, an n-type well region 5 for isolation and a p-type well region 6 are, respectively, formed. Although not shown in detail, the p-type well region 6 is formed inside the n-type well region 5 for isolation as isolated in every memory cell block 21 of the memory cell array 20. The individual p-type well regions 6 are electrically isolated from one another by means of the n-type well regions 5 for isolation.

For an impurity for forming the n-type well region 5 for isolation, phosphorus (P) is used, for example. The ion implantation of phosphorus is performed under conditions including, for example, an acceleration energy of about 2 MeV and a dosage of about 5.0e12 (5×10¹²) atoms/cm².

For an impurity used to form the p-type well region 6, boron (B) is used, for example. The ion implantation of boron is repeated three times so as to form regions (p-type semiconductor regions 6c, 6b, 6a) whose impurity concentrations as viewed from the main surface of the silicon substrate 1 toward a direction of depth are different from one another.

The first ion implantation is for the purpose of forming the p-type semiconductor region 6a and is carried out under conditions, for example, of an acceleration energy of about 150 KeV and a dosage of 2.5e12 (2.5×10¹²) atoms/cm².

The second ion implantation is to form the p-type semiconductor region 6b and is carried out under conditions, for example, of an acceleration energy of about 50 KeV and a dosage of 1.2e12 (1.2×10¹²) atoms/cm².

The third ion implantation is to form the p-type semiconductor region 6c and is carried out under conditions, for example, of an acceleration energy of about 20 KeV and a dosage of 2.5e12 (2.5×10¹²) atoms/cm².

According to the above procedure, the p-type well region 6 that has the p-type semiconductor region 6c, p-type semiconductor region 6b and p-type semiconductor region 6a arranged successively from the main surface of the silicon substrate 1 toward a direction of depth is formed. The p-type semiconductor regions 6c and 6a are formed at impurity concentrations higher than the p-type semiconductor region 6b. The p-type semiconductor region 6a is formed as having an impurity concentration lower than the p-type semiconductor region 6c. It will be noted that the p-type semiconductor region 6c is so formed that it is shallower than the junction depth Xj of n-type semiconductor region 11 of high concentration formed in a subsequent step. In Embodiment 1, the p-type semiconductor region 6b is also formed as being shallower than the junction depth of the n-type semiconductor region 11 of high concentration.

Next, after removal of the buffer insulating film 4, the insulating film 7 for charge storage made of an ONO film (silicon oxide film 7a/silicon nitride film 7b/silicon oxide film 7c) is formed on the element forming region (p-type well region 6) of the main surface of the silicon substrate 1. Although not limited, the ONO film is formed in the following way. Initially, the silicon substrate 1 is thermally treated in an atmosphere of oxygen diluted with nitrogen, and a silicon oxide film 7a having a thickness, for example, of about 2 nm is subsequently formed over the element forming region of the main surface of the silicon substrate 1. Thereafter, a silicon nitride film 6b having a thickness, for example, of 15 nm is deposited over the entire main surface of the silicon substrate 1 including the silicon oxide film 7a according to a CVD method. A silicon oxide film 7c having a thickness, for example, of about 3 nm is deposited on the silicon nitride film 7b according to the CVD method, followed by thermal treatment for densification.

In the above procedure, the silicon nitride film 7b may be replaced by an insulating film containing nitrogen in part thereof (e.g. a silicon oxide nitride film). The silicon oxide nitride film can be formed according to a CVD method using, for example, a mixed gas of a silane gas such as monosilane (SiH₄) or the like and nitrous oxide (N₂O) and a diluent gas such as helium (He) or the like.

Next, as shown in FIG. 8, a polysilicon film 8a having a thickness, for example, of 200 nm and serving as a gate material is deposited, according to a CVD method, over the entire surface of the insulating film 7 for charge storage so as to cover the element forming region of the main surface of the silicon substrate 1. Thereafter, the ion implantation of an impurity is carried out into the polysilicon film 8a in order to reduce a resistance value, and thermal treatment is carried out so as to activate an impurity injected into the polysilicon film 8a.

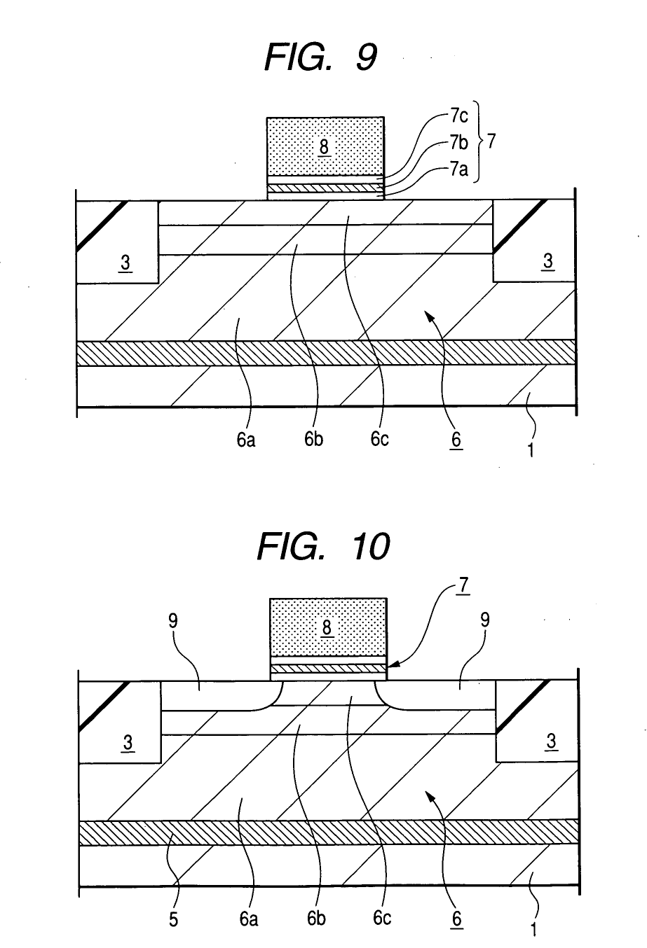

The polysilicon film 8a is subjected to patterning to form a gate electrode 8 as shown in FIG. 9. The ONO (silicon oxide film 7a/silicon nitride film 7b/silicon oxide film 7c) film is subsequently patterned using the gate electrode 8 as a mask as shown in FIG. 9. According to this step, the gate electrode 8 is formed on the element forming region (p-type well region 6) of the main surface of the silicon substrate 1 via the insulating film 7 for charge storage.

Next, an impurity is ion implanted into the element forming region (p-type well region 6) of the main surface of the silicon substrate 1 to form a pair of n-type semiconductor regions (extension regions) 9 in alignment with the gate electrode 8 as shown in FIG. 10. In this step, the n-type semiconductor region 9 is so formed as to have a junction depth Xj that is larger than the p-type semiconductor region 6c of the p-type well region 6 and is smaller than the p-type semiconductor region 6b of the p-type well region 6. For an impurity used to form the n-type semiconductor region 9, phosphorus (P) is used, for example. The ion implantation of the phosphorus is carried out under conditions including, for example, an acceleration energy of about 70 KeV and a dosage of about 7e12 (7×10¹²) atoms/cm².

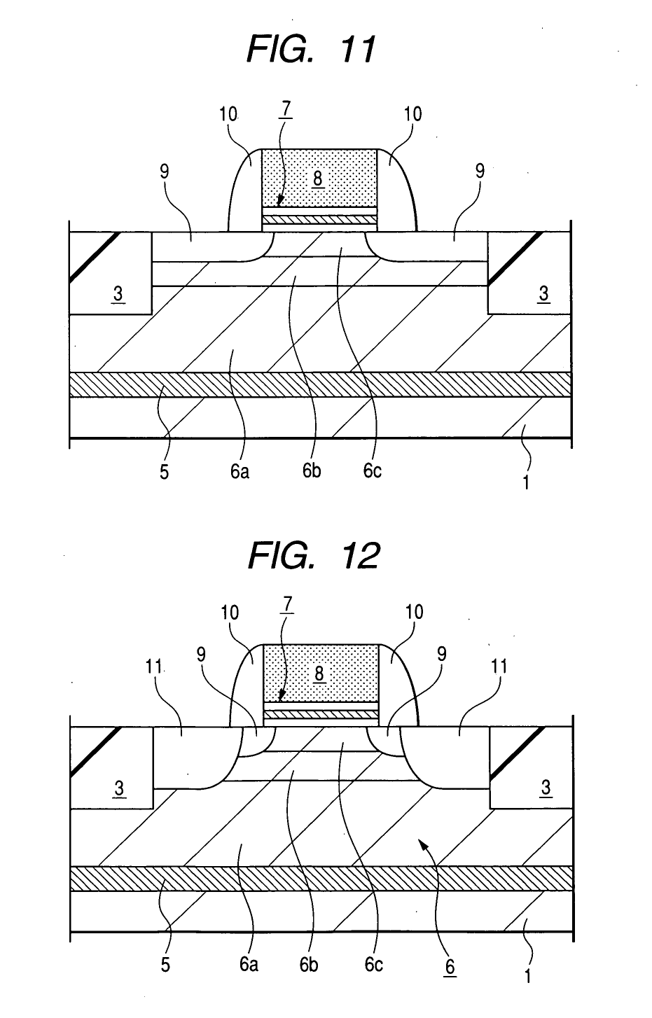

Next, as shown in FIG. 11, a side wall spacer 10 is formed at side walls along the gate length of the gate electrode 8. The side wall spacer 10 is formed by forming an insulating film made, for example, of a silicon oxide film on the entirety over the main surface of the silicon substrate 1 according to a CVD method and subjecting the insulating film to anisotropic etching such as by RIE (reactive ion etching) or the like.

Thereafter, an impurity is ion implanted into the element forming region (p-type well region 6) of the main surface of the silicon substrate 1,thereby forming a pair of n-type semiconductor regions (contact regions) 11 in alignment with the side wall spacers 10, respectively as shown in FIG. 12. In this step, the n-type semiconductor region 11 is so formed that the junction depth Xj thereof is larger than that of the p-type semiconductor region 6c of the p-type well region 6. In Embodiment 1, the n-type semiconductor region 11 is formed at a junction depth permitting contact with the p-type semiconductor region 6a of the p-type well region 6. An impurity used to form the n-type semiconductor region 11 is, for example, arsenic (As). The ion implantation of arsenic is carried out under conditions including, for example, an acceleration energy of about 40 KeV and a dosage of 3.0e15 (3×10¹⁵) atoms/cm².

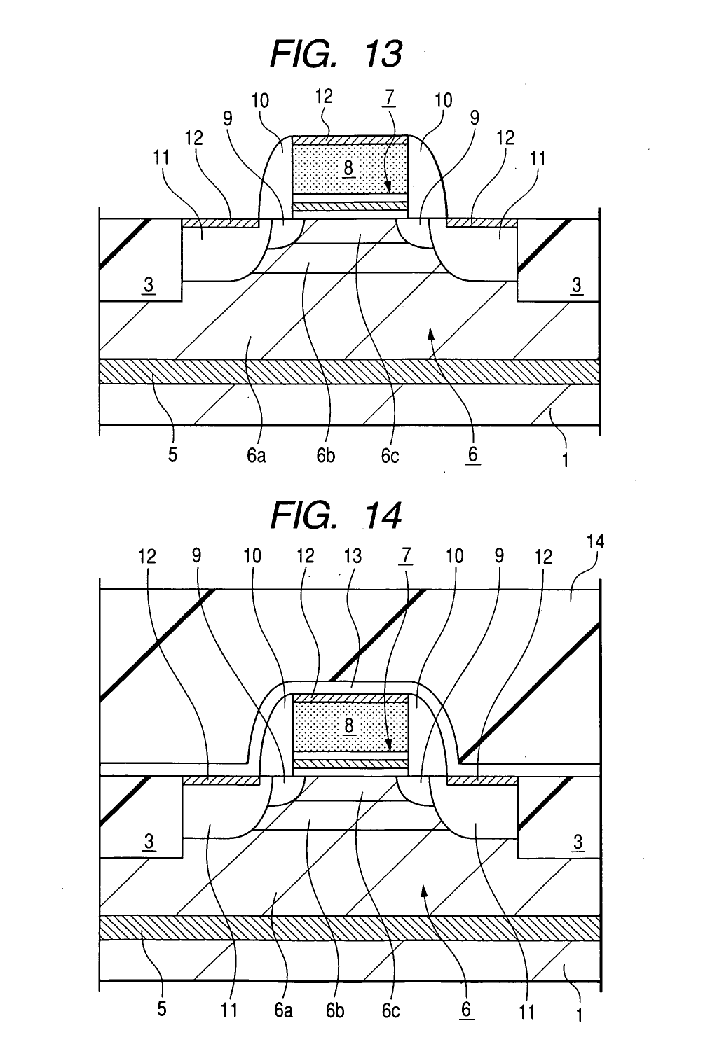

Next, as shown in FIG. 13, a cobalt silicide (CoSi) layer 12 is formed, for example, as a silicide layer (metal/semiconductor reaction layer) on the respective surfaces of the gate electrode 8 and the n-type semiconductor region 11. The cobalt silicide layer 12 is formed by removing a natural oxide film or the like to expose the surfaces of the gate electrode 8 and the n-type semiconductor region 11, forming a cobalt layer, as a high melting metal film, entirely on the main surface of the silicon substrate 1 including these surfaces, followed by thermal treatment for reaction between silicon (Si) of the gate electrode 8 and the n-type semiconductor region 11 and cobalt (Co) of the cobalt film. Thereafter, the cobalt film left unreacted on a region other than the region where the cobalt silicide layer 12 has been formed is selectively removed, followed by thermal treatment for activating the cobalt silicide layer 12. The cobalt silicide layer 12 is formed in alignment with the side wall spacer 10.

Next, an insulating film (etching stopper film) 13 made, for example, of a silicon nitride film is formed entirely on the main surface of the silicon substrate 1 including the surface of the gate electrode 8. Further, an interlayer insulating film 14 made, for example, of a silicon oxide film is formed entirely on the main surface of the silicon substrate 1, followed by planarization of the surface of the interlayer insulating film 14 by use, for example, of a CMP method as is particularly shown in FIG. 14.

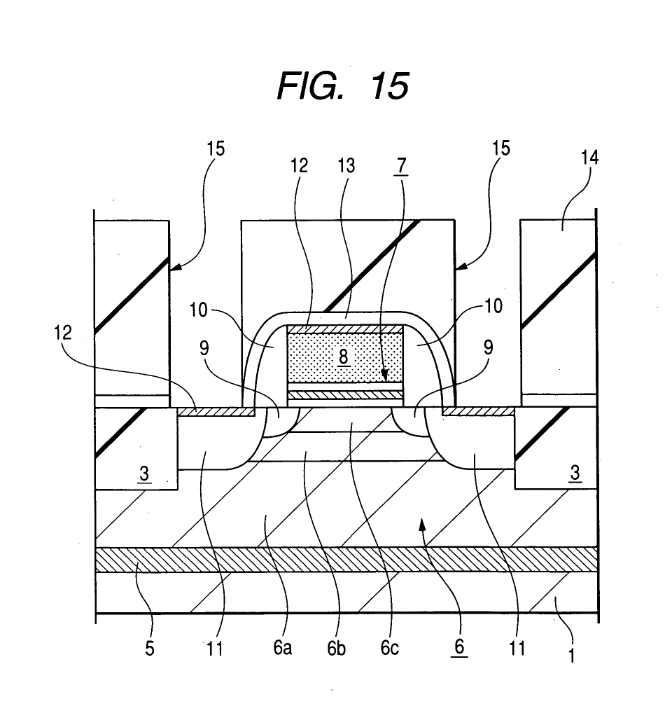

The interlayer insulating film 14 is subsequently etched and the insulating film 13 is further etched to form a connection hole 15 over the respective n-type semiconductor regions 11 as shown in FIG. 15. The connection hole 15 arrives from the surface of the interlayer insulating film 14 to the cobalt silicide layer 12.

Next, a conductor such as a metal is buried in the connection hole 15 to form a conductive plug 16. Thereafter, wirings (17s, 17d) are formed on the interlayer insulating film 14. After completion of this step, there is obtained such a structure as shown in FIG. 1.

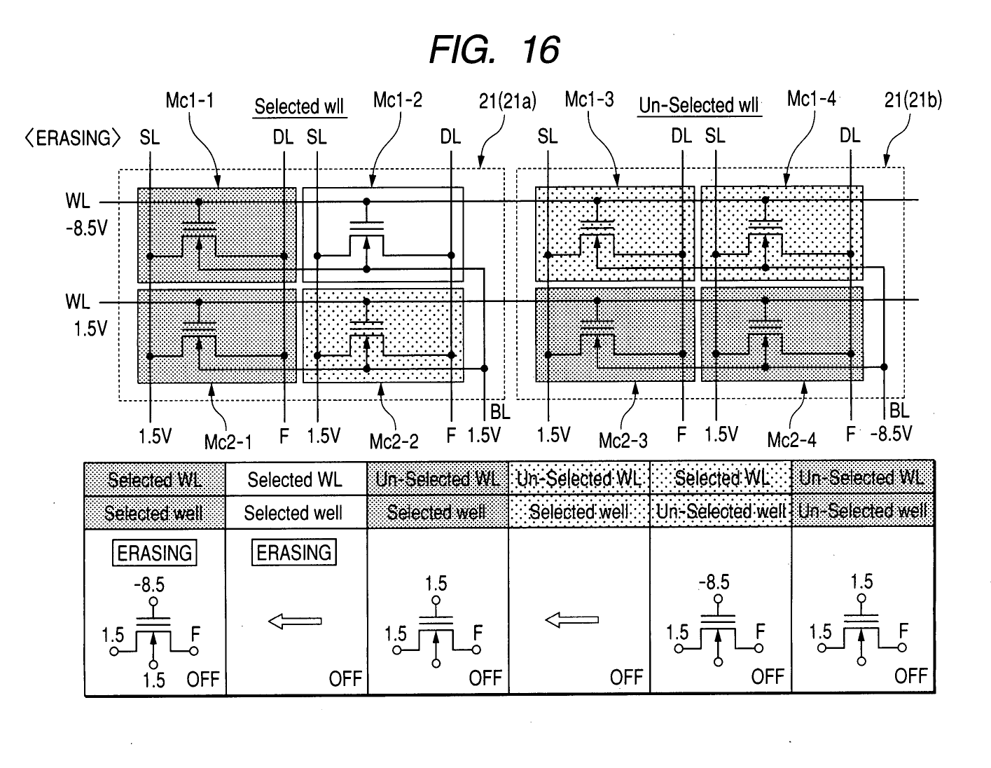

FIGS. 16 to 18 are, respectively, an equivalence circuit diagram showing an arrangement of memory cell arrays (Mc1-1 to Mc2-4) of a flush memory cell (semiconductor device) wherein the states of voltage application upon data erasing, data writing and data reading are, respectively, shown. It should be noted that WL connected to a selected memory cell is called herein “selected WL” and WL not connected to a selected memory cell is called “un-selected WL”. Likewise, a well (well region) connected to a memory cell block including a selected memory cell is called “selected well”, and a well (well region) connected to a memory cell block not including a selected memory cell is called “un-selected well”. In other words, only a memory cell connected to “selected word line” and “selected well” is classified as selected.

FIG. 16 is a view showing the state of voltage application upon erasing of data in memory cell arrays and shows an instance where Mc1-1 (or Mc1-2) is selected to conduct erasing operation. In the figure, −8.5 V or 1.5 V is applied to the word line (WL), 1.5V applied to the source line (SL), and 1.5 or −8.5 V applied to a back bias (BL) applied to the well region, and the drain (DL) serving as a data line is in a floating condition. At the time of erasing operation, −8.5 V is applied to a selected word line, 1.5 V is applied to an un-selected word line, 1.5 V is applied to a selected well, and −8.5 V is applied to an un-selected well. In Mc1-1 (or Mc1-2) under these application conditions, a potential difference of 10 V is created between the gate electrode and the well. Where such a high potential difference is applied to a memory cell in a data writing state or in a state where electrons are stored in the charge retention layer, the electrons in the charge retention layer disappear via the insulating film for charge storage at the well side according to an FN tunnel phenomenon, thereby enabling the erasing operation. On the other hand, in the memory cells other than MC1-1 (or Mc1-2), no high potential difference between the gate electrode (word line) and the well occurs. Thus, no erasing operation takes place.

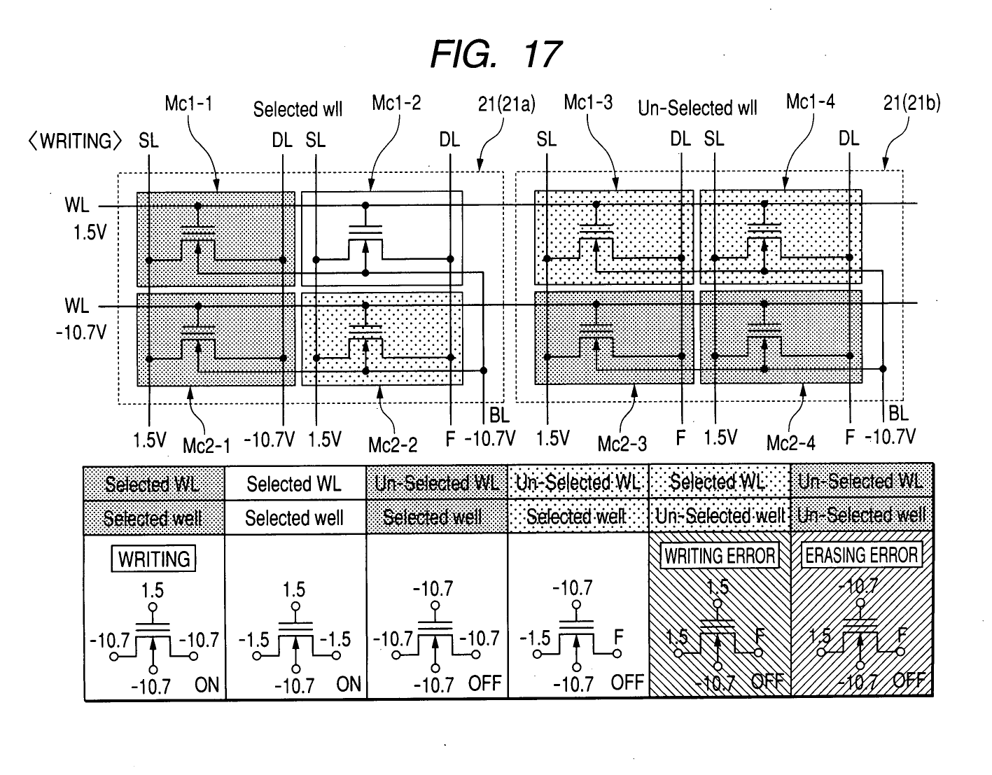

FIG. 17 is a view showing the states of voltage applications upon writing of data in memory cell arrays, and shows an instance where Mc1-1 (or Mc1-2) is selected for writing operation. In the figure, 1.5 V or −10 V is applied to WL, 1.5 V applied to SL, and −10.7 V applied to BL, and DL is applied with 1.5 V or is in a floating condition. Upon writing, 1.5 V is applied to a selected word line and −10.7 V is applied to an un-selected word line. Additionally, −10.7 V is applied to a selected well and un-selected well, respectively. In MC1-1 (or Mc1-2) applied in these applied conditions, a potential difference of 12.2 V is established between the gate electrode and the well and also between the gate electrode and the source. When such a high potential difference is applied to the memory cell in a data erased condition or in a state where electrons in the charge retention layer disappear, electrons in the charge retention layer are injected through the insulating film for charge storage at the well side according to an FN tunnel phenomenon, thereby enabling writing operation. On the other hand, in memory cells other than Mc1-1 (or Mc1-2), no high potential difference between the gate electrode and the well and also between the gate electrode and the source occurs, thereby disenabling writing operation.

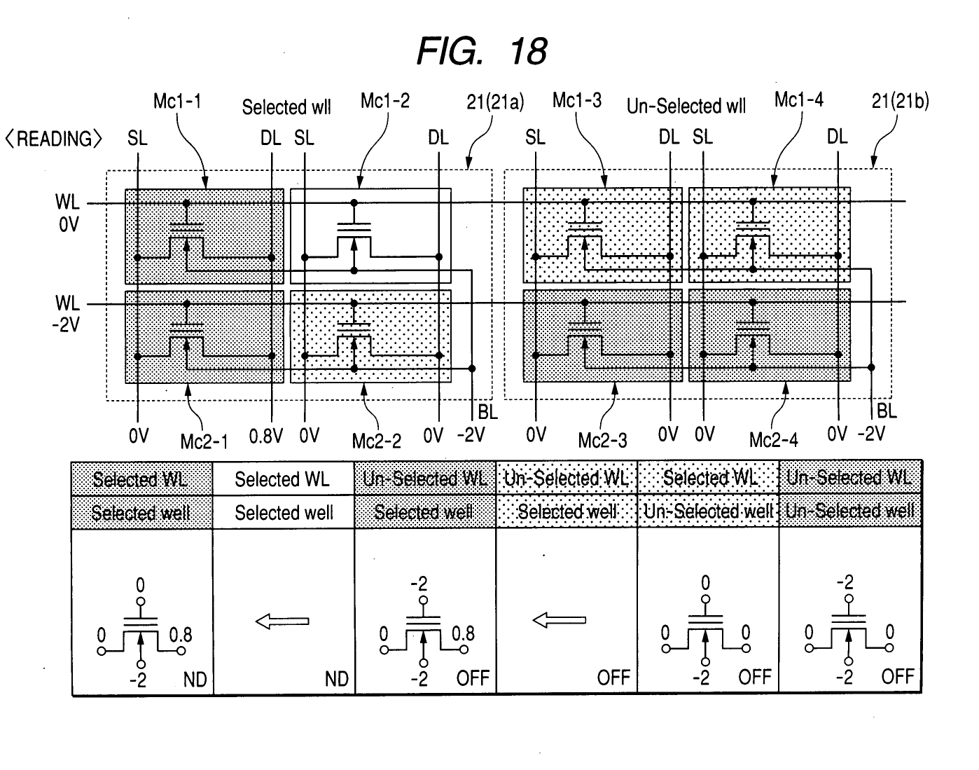

FIG. 18 is a view showing a state of voltage application at the time of reading data from a memory cell array and shows an instance where reading operation is carried out after selection of Mc1-1. In the figure, 0 V or −2 V is applied to WL, 0 V applied to SL, −2 V applied to BL and 0.8 V or 0 V applied to DL. At the time of reading operation, 0 V is applied to a selected word line and −2 V applied to unselected word lines. −2 V is applied to a selected well and unselected well. In this applied condition, reading operation is performed using an off-leak occurring by application of 0 V to the gate and 0.8 V to the drain. On the other hand, since 0 V is applied to the drain or −2 V is applied to the well of memory cells other than Mc1-1, no off leak takes place, thereby disenabling reading operation.

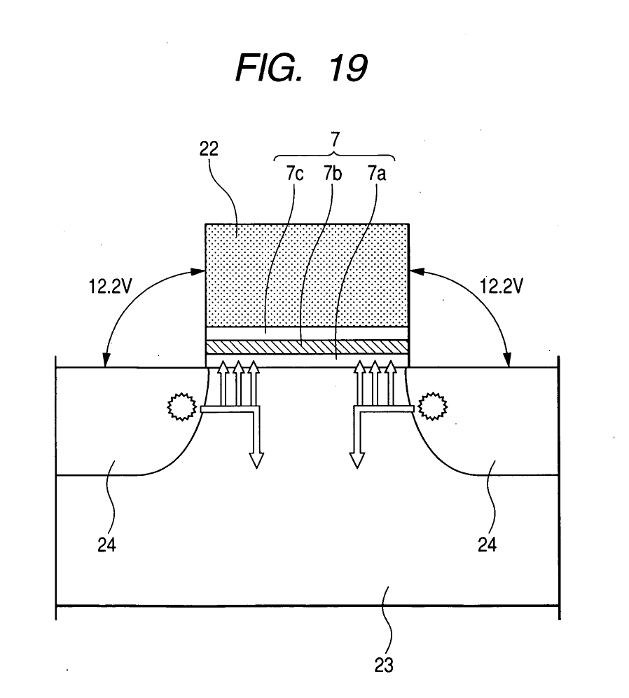

FIG. 19 is a view showing a model of disturb occurrence of a nonvolatile memory element.

In a nonvolatile MONOS memory mounted in an IC card, when a negative high voltage stress is continuedly exerted on a gate electrode 22 and a substrate (well region) 23 by means of bits (memory cell) where electrons have been injected into the charge retention layer (insulating film for charge storage (ONO film)), a disturb mode wherein a threshold voltage lowers takes place. As a result, error erasing that causes a trouble of product operation occurs. The stress leading to the disturb mode occurs as follows: because a potential difference between a diffusion layer 24 and the substrate 23 (or a gate electrode 8) is so large that hot holes are formed at the pn junction between the diffusion layer 24 and the substrate 23; and the holes are injected into the charge retention layer (i.e. a silicon nitride film 7b of an insulating film 7 for charge storage) thereby establishing the disturb. This phenomenon is suggested from the following two points.

(1) It is considered that the junction leak between the diffusion layer 24 and the substrate 23 depends strongly on the gate bias, so that the hot holes occur in the vicinity of a shallow diffusion layer below the end portion of the gate electrode 8 at which an electric field is likely to concentrate and are attracted toward the direction of charge retention layer by the influence of the negative gate bias.

(2) It is considered that the above mode is accelerated at a short channel side, so that the hot holes are attracted toward the charge retention layer by the short-channel effect accompanied by the lowering of surface potential.

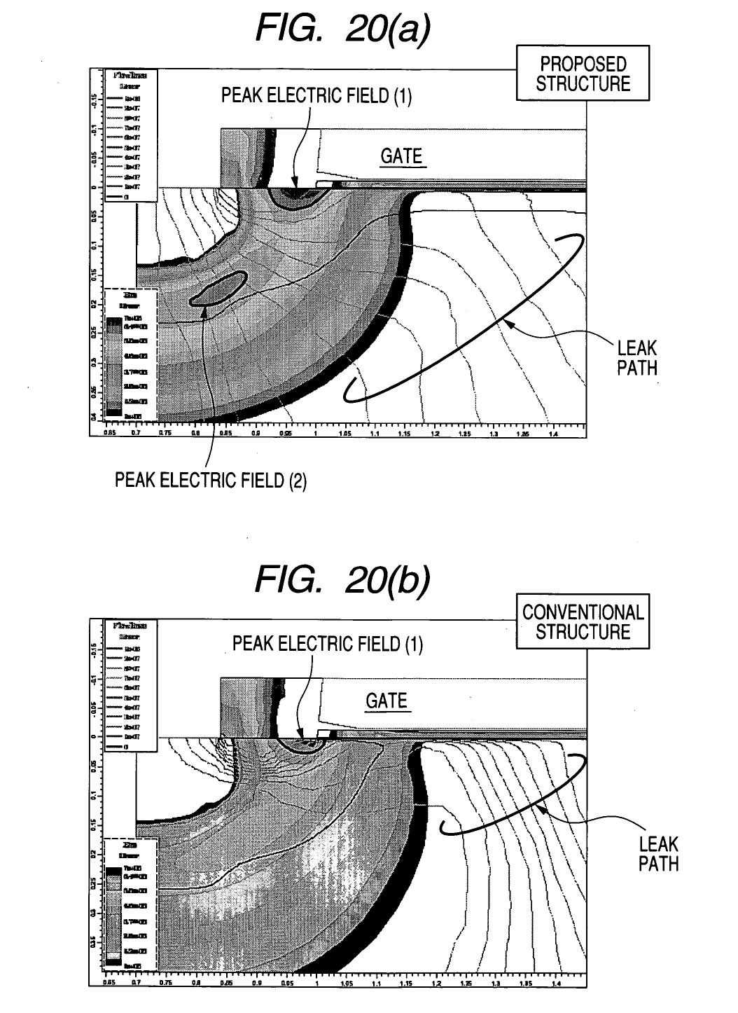

FIGS. 20(a) and 20(b) are, respectively, a view showing the results of calculation through two-dimensional simulation of an electric field and junction leak upon application of a stress capable of establishing a disturb under conditions where electrons are retained in a charge retention layer of a MONOS nonvolatile memory element. More particularly, FIG. 20(a) shows a novel structure according to the invention wherein an impurity concentration of a well region in the vicinity of the junction depth (Xj) of a deep diffusion layer is high, and FIG. 20(b) is a similar view but for a conventional structure wherein an impurity concentration of a well region in the vicinity of the junction depth (Xj) of a deep diffusion layer is not high.

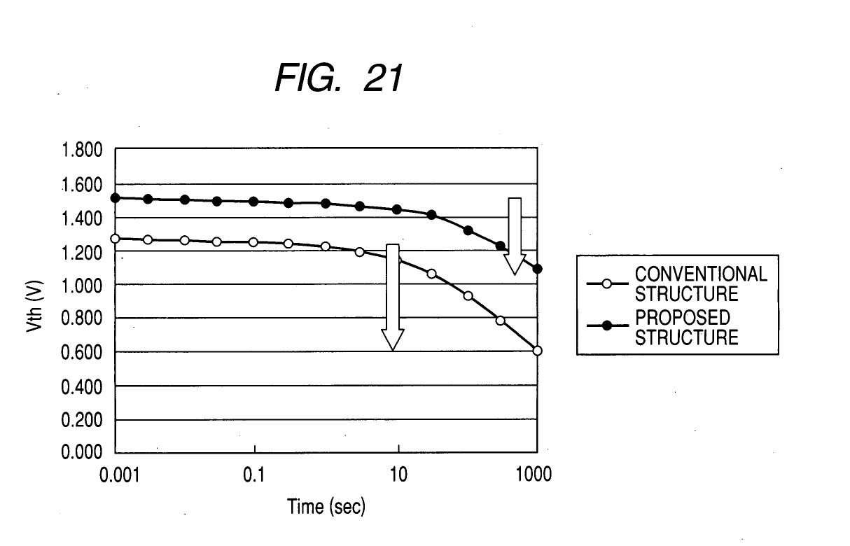

FIG. 21 is a view showing a threshold voltage (found value) in relation to the time when stress, under which a disturb occurs in a condition where electrons are retained in the charge retention layer of a nonvolatile memory element, is continuedly exerted.

As is particularly shown in FIG. 4, in Embodiment 1, an impurity concentration of a well region (p-type semiconductor region 6a) in the vicinity of the junction depth (Xj) of a deep diffusion layer (n-type semiconductor region 11) is made higher than in conventional cases.

When the impurity concentration of the well region in the vicinity of the junction depth (Xj) of the deep diffusion layer (n-type semiconductor region 11), there is formed, aside from a high concentration electric field region (peak electric field (1) in the vicinity of a shallow diffusion layer (i.e. in the vicinity of the n-type semiconductor region 9), a fresh high electric field region (peak electric filed(2)) beneath a deep diffusion layer (n-type semiconductor region 11). It will be seen that in this condition, the junction leak path is more liable to be formed as leading directly to the substrate, not through the surface portion of the substrate below the gate electrode, than in conventional structures. It will be noted that the high concentration region (p-type semiconductor region 6a) of these well regions is close in depth to the isolation region (n-type semiconductor region 5 for isolation) between the cells, so that if an implanted dosage is too great at the time of forming the high concentration region of the well region, there is concern about occurrence of leak between the cells (leak between the memory cell blocks) Moreover, if the implantation depth in the course of the formation of the high concentration region of the well region is too small, the position of occurrence of hot holes becomes closer to the gate electrode, under which the junction leak is apt to occur through the surface portion of the substrate below the gate electrode, like conventional structures. On the other hand, if the implantation depth is too deep, the high electric field region is not formed. Accordingly, the high concentration region of the well region has to be optimized with respect to an implanted energy and a dosage for every product.

FIG. 21 is a graph showing a threshold voltage (found value) in relation to the time when stress is continuedly exerted. It will be seen that the degree of lowering of the threshold voltage ascribed to disturb within a given range of time is apparently smaller for a structure where an impurity concentration at the well regions in the vicinity of the junction depth (Xj) of he deep diffusion layer (n-type semiconductor region 11) is made higher.

In this way, when a high impurity concentration in the p-type well regions 6 in the vicinity of the junction depth (Xj) of the n-type semiconductor region 11 is ensured, the fresh high electric field region (peak electric field(2)) is formed below the n-type semiconductor region 11 that is kept apart from the gate electrode 8. Thus, the position of occurrence of hot holes can be kept away from the charge retention layer (silicon nitride film 7b) of the charge storage insulating film 7, thereby permitting an injection efficiency of hot holes into the charge storage layer (silicon nitride film 7b) resulting from the application of stress thereto to be reduced.

Since the injection efficiency of the hot holes, produced as a result of application of stress, into the charge storage layer (silicon nitride film 7b) can be reduced, disturb of the MONOS nonvolatile memory element Qm, which may be a factor of causing operation troubles, can be suppressed. As a consequence, reliability of a flush memory (semiconductor device) having the MONOS nonvolatile memory element Qm can be improved.

### Embodiment 2

In a nonvolatile MONOS memory mounted in current IC cards, there exists a mode wherein a threshold voltage increases, aside from the disturb mode illustrated in the above Embodiment 1, when a negative, high voltage stress is continuously exerted on a substrate against bits wherein holes have been injected into the charge retention layer. This mode results as follows: high voltage application to the substrate has a surface potential beneath the gate electrode increased, so that electrons are injected into the charge retention layer owing to the potential difference with the charge retention layer. Accordingly, in order to avoid the disturb mode produced through the increasing threshold voltage, it becomes necessary to lower the surface potential beneath the gate electrode, for which it is effective to make the well low in concentration. However, the low concentration of the well is in trade-off relation with the disturb mode occurring through the lowering of threshold voltage.

Under these circumstance, Embodiment 2 aids at simultaneously improving the two disturb modes by rendering the well region high in concentration locally only at a portion thereof below the diffusion layer. Embodiment 2 is described in more detail.

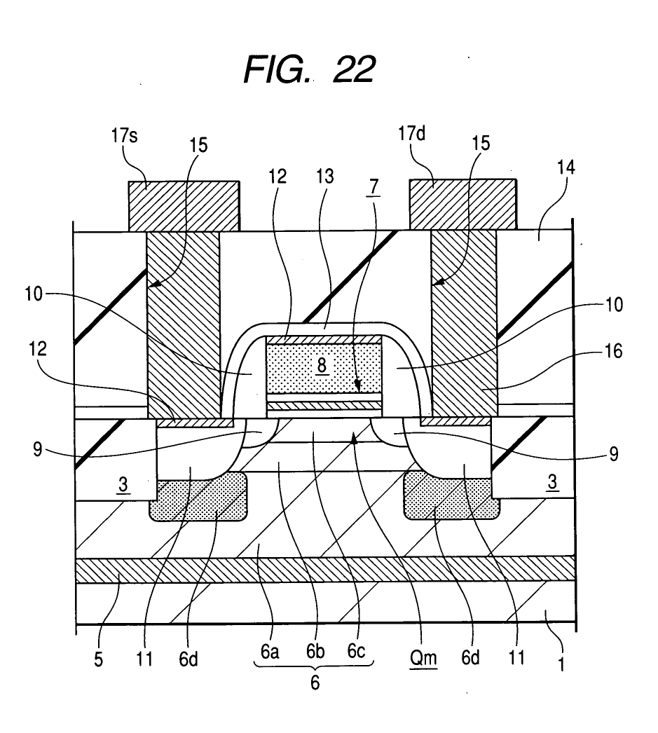

FIG. 22 is a schematic sectional view showing a brief arrangement of a nonvolatile memory element mounted in a flush memory according to Embodiment 2 of the invention. FIGS. 22 to 26 are, respectively, a schematic sectional view showing the manufacturing step of a memory flush according to Embodiment 2 of the invention.

The flush memory of Embodiment 2 is fundamentally similar in arrangement to that of Embodiment 1 described hereinabove, but with a different arrangement with respect to well region 6.

The p-type well region 6 is so arranged that it has p-type semiconductor regions 6c, 6b, 6a arranged in this order along the depth from the main surface of a silicon substrate 1, and also has a pair of p-type semiconductor regions 6d locally formed only below n-type semiconductor regions 11.

The p-type semiconductor region 6c is arranged between the source region and drain region, and in contact with the source region and drain region, and a silicon oxide film 7a of an insulating film 7 for charge storage.

The p-type semiconductor region 6b is disposed between the source region and drain region, and is located at a position deeper than the p-type semiconductor region 6c toward the direction of depth from the main surface of the silicon substrate 1. The region 6b is in contact with the source, the drain region and p-type semiconductor region 6c.

The p-type semiconductor region 6a is located at a position deeper than the p-type semiconductor region 6b toward the direction of depth from the main surface of the silicon substrate 1 and is arranged in contact with the source region, drain region and p-type semiconductor region 6c.

The pair of p-type semiconductor regions 6d is arranged at a position deeper than the n-type semiconductor region 11 toward the direction of depth from the main surface of the silicon substrate 1 and in contact with the respective n-type semiconductor regions 11. The paired p-type semiconductor regions 6d are provided such that they are kept apart from each other along the gate length of the gate electrode 8 and are formed in alignment with the side wall spacers 10 at side walls of the gate electrode 8, respectively.

The p-type semiconductor region 6c is formed as having an impurity concentration higher than the p-type semiconductor region 6b. The p-type semiconductor region 6b is formed at an impurity concentration higher than the p-type semiconductor region 6a. The p-type semiconductor region 6d is formed at an impurity concentration higher than the p-type semiconductor regions 6b and 6a. The junction depth Xj (depth from the main surface of the substrate) of the pair of n-type semiconductor regions 11 that are, respectively, a source region and drain region is greater than the p-type semiconductor region 6c, and is greater than the p-type semiconductor region 6b in this embodiment 2.

As set forth hereinabove, since the p-type semiconductor regions 6c and 6d are, respectively, higher in impurity concentration than the p-type semiconductor regions 6b and 6a, the p-type well region 6 is so arranged as to have a first impurity concentration peak made of an impurity distribution of the p-type semiconductor region 6c and a second impurity concentration peak made of an impurity distribution of the p-type semiconductor region 6d. The first impurity concentration peak (p-type semiconductor region 6c) is positioned at a region shallower than the junction depth Xj of the n-type semiconductor region 11. The second impurity concentration peak (p-type semiconductor region 6a) is positioned at a region deeper than the junction depth Xj of the n-type semiconductor region 11, and is located in the vicinity of the junction depth Xj of the p-type semiconductor region 11.

When the nonvolatile memory element Qm arranged in this way is applied with voltages to the gate electrode 8 and the p-type well region 6 like the foregoing Embodiment 1, a first high electric field region is established at a surface portion below the end of the gate electrode 8 in the source region, and a second high electric field region is established at a junction between the source region (n-type semiconductor region 11) and the p-type semiconductor region 6d.

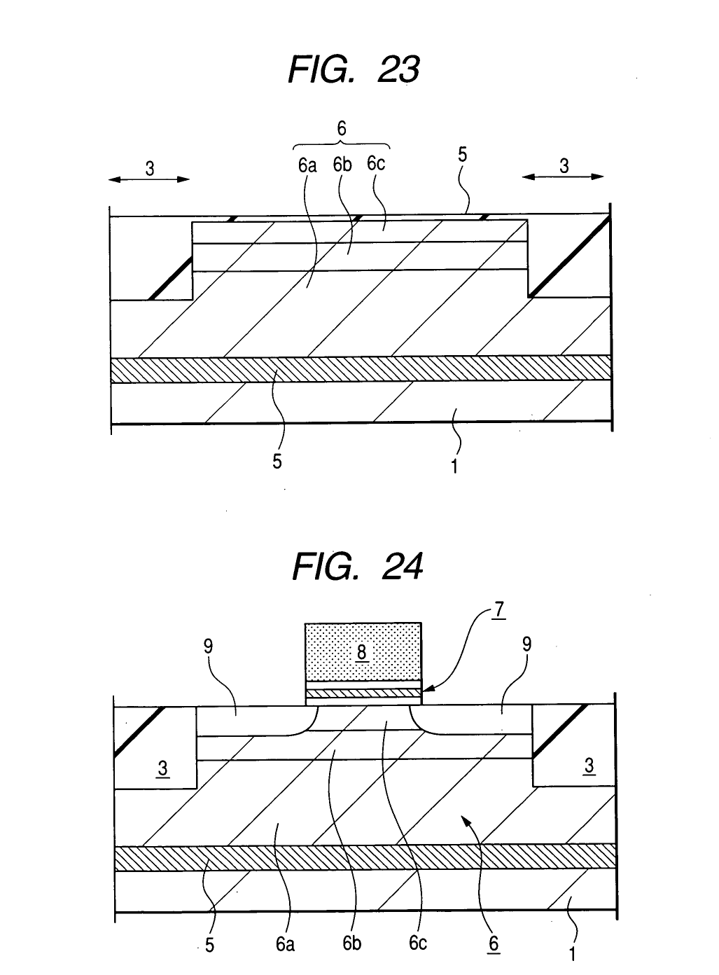

Next, the manufacture of the flush memory of Embodiment 2 is described with reference to FIGS. 23 to 26. It will be noted that the flush memory of Embodiment 2 is fundamentally similar in arrangement to that of the foregoing Embodiment 1, and illustration is made mainly of different steps or procedures.

Initially, similar steps of Embodiment 1 are repeated until the buffer insulating film 4 is formed. Thereafter, an impurity is ion implanted into the main surface of the silicon substrate 1, followed by thermal treatment to activate the impurity to form the n-type well region 5 for isolation and the p-type well region 6 as shown in FIG. 23. The n-type semiconductor region 5 for isolation is formed under similar conditions as in the foregoing Embodiment 1.

For an impurity used to form the p-type well region, boron (B) is used, for example. The ion implantation of boron is repeated three times to form regions with different impurity concentrations (p-type semiconductor regions 6c, 6b, 6a) along the depth from the main surface of the silicon substrate 1.

The first ion implantation is for the purpose of forming the p-type semiconductor region 6a and is carried out under conditions including, for example, an acceleration energy of about 150 KeV and a dosage of about 2.5e12 (2.5×10¹²) atoms/cm².

The second ion implantation is to form the p-type semiconductor region 6b and is carried out under conditions including, for example, an acceleration energy of about 50 KeV and a dosage of about 1.2e12 (1.2×10¹²) atoms/cm².

The third ion implantation is to form the p-type semiconductor region 6c and is carried out under conditions including, for example, an acceleration energy of about 20 KeV and a dosage of about 2.5e12 (2.5×10¹²) atoms/cm².

According to the above procedure, there is formed the p-type well region 6 having the p-type semiconductor region 6c, p-type semiconductor region 6b and p-type semiconductor region 6c arranged in this order along the depth from the main surface of the silicon substrate 1. The p-type semiconductor region 6c is formed at a higher impurity concentration than the p-type semiconductor region 6b, and the p-type semiconductor region 6b is formed at a higher impurity concentration than the p-type semiconductor region 6a. It will be noted that the p-type semiconductor region 6c is formed more shallowly than the junction depth Xj of the n-type semiconductor region 11 of high concentration formed in a subsequent step. In Embodiment 2, the p-type semiconductor region 6b is also formed more shallowly than the junction depth of the highly concentrated n-type semiconductor region 11.

Next, after removal of the buffer insulating film 4, an insulating film 7 for charge storage, a gate electrode 8 and a pair of n-type semiconductor regions 9 are, respectively, formed according to similar steps as in the foregoing Embodiment 1.

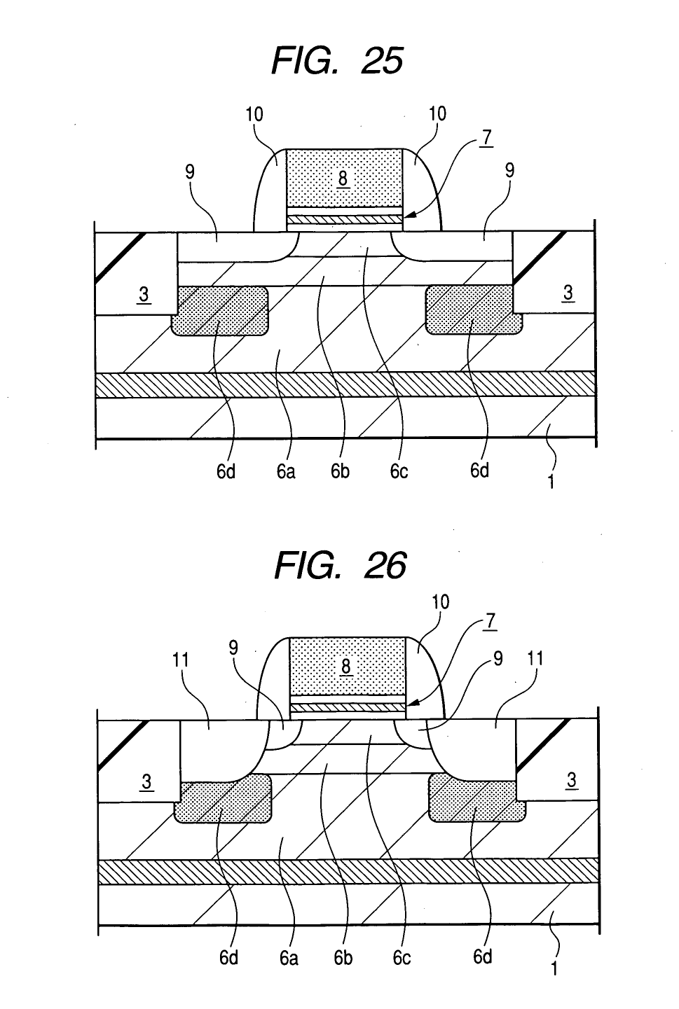

Thereafter, after formation of a side wall spacer 10 at side walls of the gate electrode 8 by similar steps as in Embodiment 1, an impurity was ion implanted into the element forming region (p-type well region 6) of the main surface of the silicon substrate 1 to form a pair of p-type semiconductor regions 6d in alignment with the side wall spacers 10 as shown in FIG. 25. In this step, the p-type semiconductor region 6d is formed more deeply than the junction depth Xj of a pair of n-type semiconductor regions 11 formed in a subsequent step at a region that is in contact with the n-type semiconductor region Boron (B) is used, for example, as an impurity used to form the p-type semiconductor region 6d. The ion implantation of boron is carried out under conditions including, for example, an acceleration energy of about 90 KeV and a dosage of about 3.0e12 (3×10¹²) atoms/cm².

According to this step, the well region 6 having the p-type semiconductor regions 6a to 6d is formed.

Next, according to similar steps as in the foregoing Embodiment 1, a pair of n-type semiconductor regions 11 are formed as shown in FIG. 26, followed by similar steps as in Embodiment 1 until wirings 17d, 17s are formed, thereby providing a structure shown in FIG. 22.

In this manner, the impurity concentration of the p-type well region 6 in the vicinity of the junction depth Xj of the n-type semiconductor region 11 is increased by means of the p-type semiconductor region 6d, and thus, a fresh high electric field region (peak electric field (2)) is formed below the n-type semiconductor region 11 that is kept apart from the gate electrode 8. Hence, the position of occurrence of hot holes can be kept away from the charge retention layer (silicon nitride film 7b) of the insulating film 7 for charge storage, so that the injection efficiency of hot holes occurring by application of stress into the charge storage layer (silicon nitride film 7b) can be reduced.

Further, the well region 6 is locally rendered high in concentration only below the n-type semiconductor region 11 by providing the p-type semiconductor region 6d. This leads to a lowering of surface potential beneath the gate electrode. As a result, the injection efficiency of electrons occurring by application of stress into the charge storage layer (silicon nitride film 7b) can be lowered.

Since the injection efficiency of electrons occurring by application of stress into the charge storage layer (silicon nitride film 7b) can be reduced, error writing of the MONOS nonvolatile memory element Qm, which is a factor of causing operation troubles, can be suppressed. As a result, reliability of the flush memory (semiconductor device) having the MONOS nonvolatile memory element Qm can be improved.

The invention has been described by way of embedments, which should not be construed as limiting the invention thereto. As a matter of course, various modifications and variations may be made without departing from the spirit of the invention.

1. A semiconductor device comprising a well region of a first conduction type formed in a main surface of a semiconductor substrate, and a nonvolatile memory element formed at the well region of the first conduction type,
wherein the nonvolatile memory element comprises:
a gate electrode formed over the well region of the first conduction type through an insulating film for charge storage; and
a source region and drain region of a second conduction type which are separated from each other along a gate length of the gate electrode and are disposed in the well region of the first conduction type,
wherein the well region of the first conduction type comprises:
a third semiconductor region arranged between the source region and the drain region and in contact with the source region, the drain region and the insulating film for charge storage;
a second semiconductor region which is disposed between the source region and the drain region and which is arranged at a position deeper than the third semiconductor region toward a direction of depth from the main surface of the semiconductor substrate and in contact with the source region, the drain region and the third semiconductor region; and
a first semiconductor region that is arranged at a position deeper than the second semiconductor region toward a direction of depth from the main surface of the semiconductor substrate and in contact with the source region, the drain region and the second semiconductor region, and
wherein the first and third semiconductor regions are higher in impurity concentration than the second semiconductor region.

2. The semiconductor device according to claim 1,
wherein a junction depth of the source region and the drain region is greater than the third semiconductor region.

3. The semiconductor device according to claim 1,
wherein the first semiconductor region is lower in impurity concentration than the third semiconductor region.

4. The semiconductor device according to claim 1,
wherein when a potential is applied to the gate electrode and the well region of the first conduction type, a high electric field region is established at a junction between the source region and the first semiconductor region.

5. The semiconductor device according to claim 1,
wherein when a potential is applied to the gate electrode and the well region of the first conduction type, a first high electric field region is established at a surface portion below an end portion of the gate electrode in the source region, and a second high electric filed region is established at a junction between the source region and the first semiconductor region.

6. The semiconductor device according to claim 1,
wherein the insulating film for charge storage is made of a film including a nitride film.

7. The semiconductor device according to claim 1,
wherein the insulating film for charge storage is formed of a film including a nitride film, and the nonvolatile memory element is arranged such that data is written therein by injecting electrons from a side of the semiconductor substrate into the nitride film of the insulating film for charge storage.

8. The semiconductor device according to claim 1,
wherein the source region and the drain region include the first semiconductor region of a second conduction type formed in alignment with the gate electrode, and the second semiconductor region of a second conduction type which is formed in alignment with a side wall spacer provided at side walls of the gate electrode, and which has an impurity concentration higher than the first semiconductor type, and
wherein the second semiconductor region of the second conduction type has a junction depth greater than the third conductor region of the well region of the first conduction type.

9. A semiconductor device comprising a well region of a first conduction type formed in a main surface of a semiconductor substrate and a nonvolatile memory element formed in the well region of the first conduction type,
wherein the nonvolatile memory element includes:
a gate electrode formed over the well region of the first conduction type through an insulating film for charge storage; and
a source region and a drain region, both being of a second conduction type, which are positioned in the well region of the first conduction type as being kept apart from each other along a gate length of the gate electrode, and
wherein the well region of the first conduction type has first and second impurity concentration peaks in an impurity concentration distribution as viewed from the main surface of the semiconductor substrate toward a direction of depth,
the first impurity concentration peak being located at a region shallower than the source region and the drain region, and the second impurity concentration peak being located at a region deeper than the source region and the drain region.

10. The semiconductor device according to claim 9,
wherein the second impurity concentration peak is located in the vicinity of a junction depth of the source region and the drain region.

11. The semiconductor device according to claim 9,
wherein when a potential is applied to the gate electrode and the well region of the first conduction type, a high electric field region is established at a junction between the source region and the well region.

12. The semiconductor device according to claim 9,
wherein when a potential is applied to the gate electrode and the well region of the first conduction type, a first high electric filed region is formed at a surface portion below an end portion of the gate electrode in the source region, and a second high electric filed region is established at a junction between the source region and the well region.

13. The semiconductor device according to claim 9,
wherein the insulating film for charge storage is made of a film including a nitride film.

14. The semiconductor device according to claim 9,
wherein the insulating film for charge storage is formed of a film including a nitride film, and the nonvolatile memory element is arranged such that data is written therein by injecting electrons from a side of the semiconductor substrate into the nitride film of the insulating film for charge storage.

15. The semiconductor device according to claim 9,
wherein the source region and the drain region include: a first semiconductor region of a second conduction type formed in alignment with the gate electrode; and a second semiconductor region of a second conduction type, which is formed in alignment with a side wall spacer provided at side walls of the gate electrode, and which has an impurity concentration higher than the first semiconductor region of the second conduction type, and
wherein the second semiconductor region of the second conduction type has a junction depth greater than the third conductor region of the well region of the first conduction type.

16. A semiconductor device comprising a well region of a first conduction type formed in a main surface of a semiconductor substrate, and a nonvolatile memory element formed in the well region of the first conduction type,
wherein the nonvolatile element includes:
a gate electrode formed over the well region of the first conduction type through an insulating film for charge storage; and
a source region and a drain region of a second conduction type arranged in the well region of the first conduction type as being kept apart from each other along a gate length of the gate electrode,
wherein the well region of the first conduction type comprises:
a third semiconductor region arranged between the source region and the drain region and in contact with the source region, the drain region and the insulating film for charge storage;
a second semiconductor region which is disposed between the source region and the drain region, which is arranged at a position deeper than the third semiconductor region toward a direction of depth from the main surface of the semiconductor substrate and is in contact with the source region, the drain region and the third semiconductor region, and which has an impurity concentration lower than the third semiconductor region; and
a first semiconductor region that is arranged at a position deeper than the second semiconductor region toward a direction of depth from the main surface of the semiconductor substrate and in contact with the source region, the drain region and the second semiconductor region, and which has an impurity concentration lower than the second semiconductor region,
wherein a pair of fourth semiconductor regions of a first conduction type is arranged between the source and drain regions and the first semiconductor region in the direction of depth of the semiconductor substrate as being kept apart from each other along a gate length of the gate electrode, and
wherein the fourth semiconductor regions has an impurity concentration higher than the first and second semiconductor regions.

17. The semiconductor device according to claim 16,
wherein one of the paired fourth semiconductor regions is in contact with the source region, and the other fourth semiconductor region is in contact with the drain region.

18. The semiconductor device according to claim 16,
wherein when a potential is applied to the gate electrode and the well region of the first conduction type, a high electric field region is established at a junction between the source region and the fourth semiconductor region.

19. The semiconductor device according to claim 16,
wherein when a potential is applied to the gate electrode and the well region of the first conduction type, a first high electric region is established at a surface portion below an end portion of the gate electrode of the source region, and a second high electric field region is established at a junction between the source region and the fourth semiconductor region.

20. The semiconductor device according to claim 16,
wherein the insulating film for charge storage is made of a film including a nitride film.

21. The semiconductor device according to claim 16,
wherein the insulating film for charge storage is formed of a film including a nitride film, and the nonvolatile memory element is arranged such that data is written therein by injecting electrons from a side of the semiconductor substrate into the nitride film of the insulating film for charge storage.

22. The semiconductor device according to claim 16,
wherein the source region and the drain region include a first semiconductor region of a second conduction type formed in alignment with the gate electrode, and a second semiconductor region of a second conduction type which is in alignment with a side wall spacer provided at side walls of the gate electrode, and which has an impurity concentration higher than the first semiconductor region of the second conduction type, and
wherein the fourth semiconductor region of the first conduction type is disposed at a position deeper than the second semiconductor region of the second conduction type.

23-26. (canceled)
